(19) United States
(12) Patent Application Publication
(10) Pub. No.: US 2012/0182032 A1
(43) Pub. Date: Jul. 19, 2012

(54) TEST MODE CONTROLLER AND ELECTRONIC APPARATUS WITH SELF-TESTING THEREOF

(75) Inventors: KUO-CHIANG CHEN, NEW TAIPEI CITY (TW); YEN-YI CHEN, NEW TAIPEI CITY (TW)

(73) Assignee: FORTUNE SEMICONDUCTOR CORPORATION, NEW TAIPEI CITY (TW)

(21) Appl. No.: 13/008,143

(22) Filed: Jan. 18, 2011

(51) Int. Cl. G01R 31/3187

(52) U.S. Cl. 324/750.3

(57) ABSTRACT

A test mode controller comprises an enable signal generator, a control signal generator, and a latch. The enable signal generator receives a power signal and a second control signal, and generates a first enable signal and a second enable signal respectively to the latch and the control signal generator. The control signal generator receives a power indicating voltage and a reference voltage, and generates the first control signal to the latch when the first enable signal is enabled. The latch receives the first control signal, and generates the second control signal according to the first control signal when the second enable signal is enabled. The second control signal controls a chip to operate in a test mode or a normal mode. Accordingly, the test mode controller may reduce the test time without a test pin, and may also reduce the chip area and the package cost.

### BACKGROUND

1. Technical Field

The present disclosure relates to an electronic apparatus with self-testing, in particular, to a test mode controller and the electronic apparatus with self-testing thereof.

2. Description of Related Art

The widely used electronic apparatuses in the current market are implemented in a chip by the integration circuit technology. When the manufacturer produces the chips, not only the performance is considered, but also the chip area and the package cost corresponding to the number of pins are considered. Accordingly, most manufacturers are dedicated to reduce the chip area and the number of pins when producing the chips.

Taking a conventional protection circuit for the single cell Li battery for example, the conventional chip requires the additional at least one test pin to reduce the test time. Referring to FIG. 1, FIG. 1 is a circuit diagram showing the conventional protection circuit for the single cell Li battery. The conventional protection circuit for the single cell Li battery 1 comprises a single cell Li battery 10, a protection chip for the single cell Li battery 11, a power MOS transistor circuit 12, multiple resistors R1, R2, and a capacitor C1. In addition, the protection chip for the single cell Li battery 11 has multiple control pins of power MOS transistors OC, OD, a power pin VCC, a ground pin GND, a test pin ID, and a power indication pin CS. The power MOS transistor circuit 12 has multiple power MOS transistors M1, M2, and multiple diodes D1, D2. The connections of all elements of the conventional protection circuit for the single cell Li battery 1 are shown in FIG. 1, therefore omitting the detailed description herein.

The protection chip for the single cell Li battery 11 outputs the controls signals on the control pins of the power MOS transistors OC, OD, to control operations of the power MOS transistors M1 and M2 in the power MOS transistor circuit 12, and hence over-charging, over-discharging, and over-current protection can be achieved. It is noted that, the test pin TD of the protection chip for the single cell Li battery 11 is merely used in the test mode. When the protection chip for the single cell Li battery 11 needs to operate in the test mode, the test pin TD is applied with an external voltage, such that the test time can reduced. However, when the protection chip for the single cell Li battery 11 operates in the normal mode, the test pin TD is floated.

Accordingly, the protection chip for the single cell Li battery 1 may waste the chip area and the package cost due to the additional test pin ID. In the similar manner, the conventional chip may also require the test pin, therefore introducing the similar problems.

### SUMMARY

An exemplary embodiment of the present disclosure provides test mode controller, and the test mode controller comprises an enable signal generator, a control signal generator and a latch. The enable signal generator receives a second control signal output from the latch and a power signal, and correspondingly generates a first enable signal and a second enable signal respectively to the latch and the control signal generator. The control signal generator generates a first control signal to the latch. The latch receives the first control signal generated from the control signal generator, and generates the second control signal to the enable signal generator. The control signal generator receives a power indicating voltage and a reference voltage, and generates first control signal according to the power indicating voltage and reference voltage when the first enable signal is enabled. The latch is controlled by the second enable signal, and outputs the second control signal according to the first control signal when the second enable signal is enabled. The second control signal is used to control a chip to operate in a test mode or a normal mode.

An exemplary embodiment of the present disclosure provides an electronic apparatus with self-testing, and the electronic apparatus with self-testing comprises a chip and the above test mode controller.

Accordingly, the test mode controller and the electronic apparatus with self-testing provided by the exemplary embodiments of the present disclosure may not reserve the test pin required by the conventional chip, but still may reduce the test time as the conventional chip with the test pin. Therefore, the chip area and the package cost of the electronic apparatus with self-testing provided by the exemplary chip of the present disclosure may be lower than those of the conventional chip with the test pin.

In order to further understand the techniques, means and effects the present disclosure, the following detailed descriptions and appended drawings are hereby referred, such that, through which, the purposes, features and aspects of the present disclosure can be thoroughly and concretely appreciated; however, the appended drawings are merely provided for reference and illustration, without any intention to be used for limiting the present disclosure.

### BRIEF DESCRIPTION OF THE DRAWINGS

FIG. 1 is a circuit diagram showing a conventional protection circuit for the single cell Li battery.

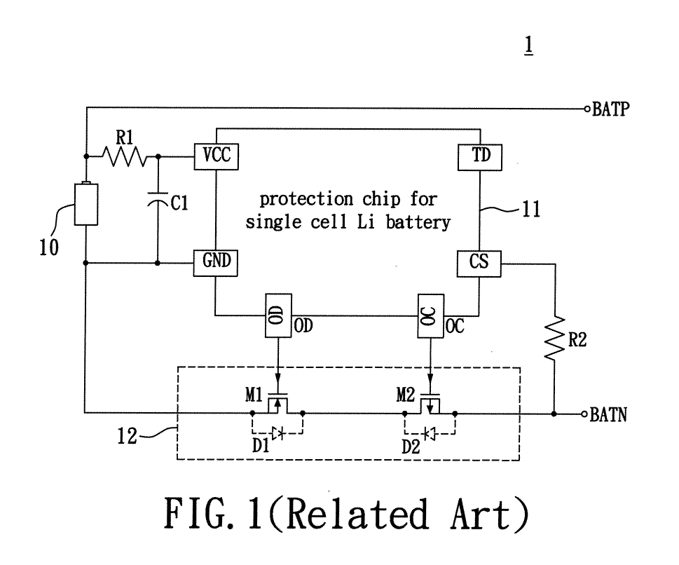

FIG. 2 is a circuit diagram showing a test mode controller according to one exemplary embodiment of the present disclosure.

FIG. 3 is a waveform diagram showing waveforms of multiple signals generated by the test mode controller in FIG. 2 according to one exemplary embodiment of the present disclosure.

FIG. 4 is a circuit diagram showing a test mode controller according to another one exemplary embodiment of the present disclosure.

FIG. 5 is a waveform diagram showing waveforms of multiple signals generated by the test mode controller in FIG. 4 according to one exemplary embodiment of the present disclosure.

FIG. 6 is a waveform diagram showing waveforms of multiple signals generated by the test mode controller in FIG. 2 according to another one exemplary embodiment of the present disclosure.

FIG. 7 is a circuit diagram showing a test mode controller according to another one exemplary embodiment of the present disclosure.

FIG. 8 is a waveform diagram showing waveforms of multiple signals generated by the test mode controller in FIG. 7 according to one exemplary embodiment of the present disclosure.

FIG. 9 is a circuit diagram showing an electronic apparatus with self-testing according to one exemplary embodiment of the present disclosure.

### DESCRIPTION OF THE EXEMPLARY EMBODIMENTS

### An Exemplary Embodiment of The Test Mode Controller

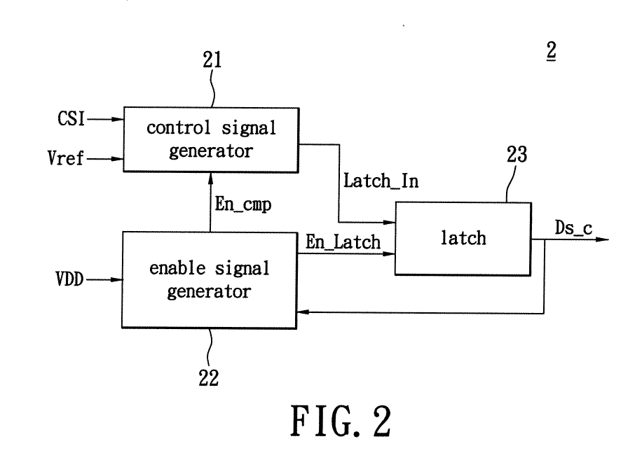

Referring to FIG. 2, FIG. 2 is a circuit diagram showing a test mode controller according to one exemplary embodiment of the present disclosure. The test mode controller 2 comprises an enable signal generator 22, a control signal generator 21, and a latch 23. The control signal generator 21 is electrically coupled to the enable signal generator 22 and latch 23, and the latch 23 is electrically coupled to the enable signal generator 22.

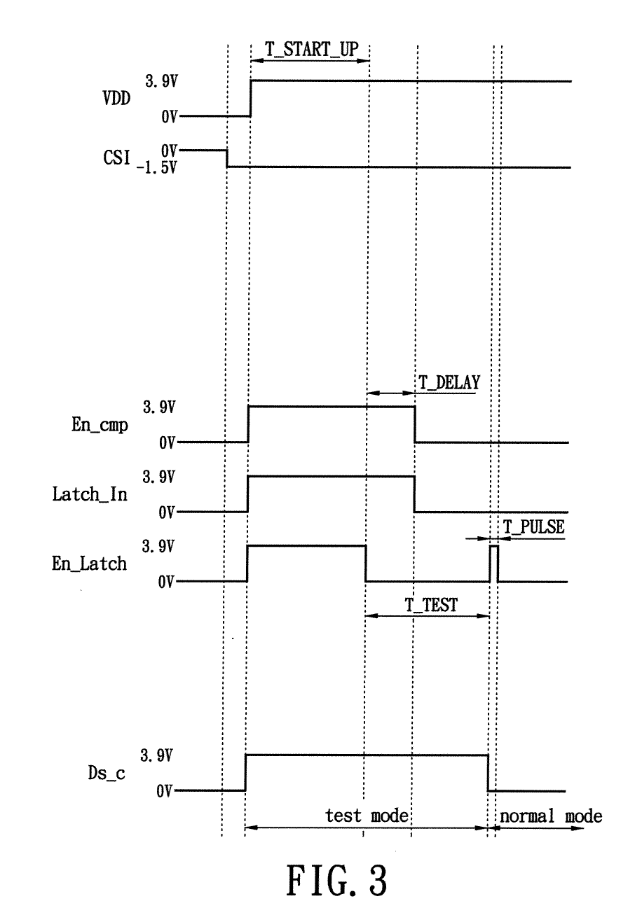

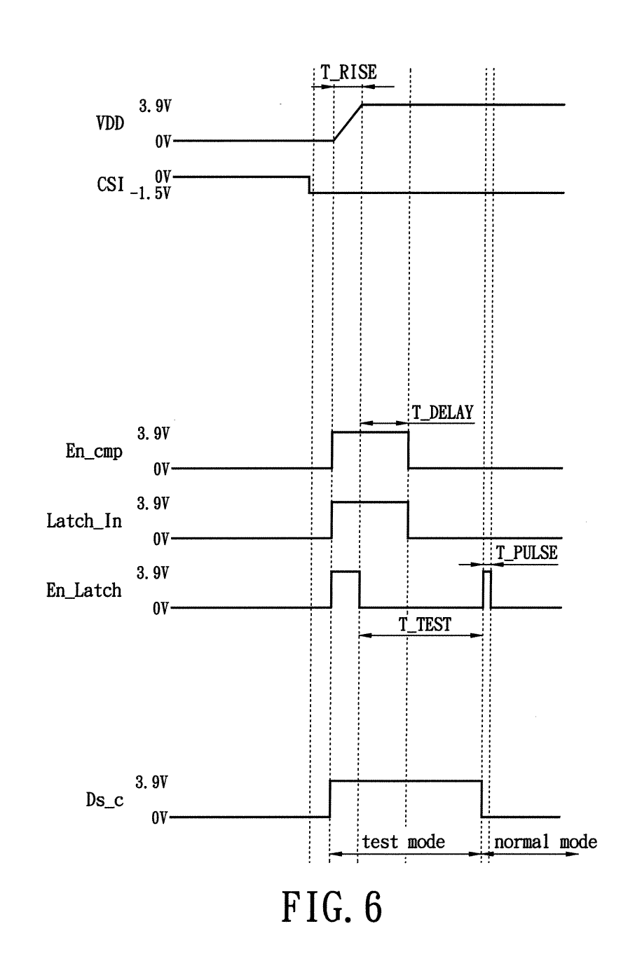

The enable signal generator 22 receives the power signal VDD and the second control signal Ds_c generated from the latch 23, and generates the first enable signal En_cmp and the second enable signal En_Latch correspondingly, wherein the first enable signal En_cmp and the second enable signal En_latch are respectively transmitted to the latch 23 and the control signal generator 21. The enable and disable timing of first enable signal En_cmp is illustrated in FIG. 3 or FIG. 6, and in the similar manner, the enable and disable timing of the second enable signal En_latch is also illustrated in FIG. 3 or FIG. 6.

The control signal generator 21 receives the power indicating voltage CSI and the reference voltageVref, and generates the first control signal Latch_In according to the power indicating voltage CSI and the reference voltage Vref when the first enable signal En_cmp is enabled (such as the high voltage level of 3.9V). The control signal generator 21 outputs the first control signal with the first level (such as the low voltage level of 0V) when the first enable signal En_cmp is disabled (such as the low voltage level of 0V). To put it concretely, the control signal generator 21 generates the first control signal En_cmp with the second level (such as the high voltage level of 3.9V) when the first enabled signal En_cmp is enabled, the reference voltage Vref is a positive voltage, and the power indicating voltage CSI is externally connected to a negative voltage (such as −1.5V). The first control signal Latch_In generated by control signal generator 21 is then transmitted the latch 23.

The latch 23 receives the first control signal Latch_In generated by the control signal generator 21, and correspondingly generates the second control signal Ds_c to the enable signal generator 22. The latch 23 is controlled by the second enable signal En_latch, and outputs the second control signal Ds_c according to the first control signal Latch_In when the second enable signal En_latch is enabled. The latch 23 is a D latch for example, and the type of the latch 23 is not intended to limit the scope of the present disclosure. The second control signal Ds_c is the first level when the second enable signal En_latch is enabled and the first control signal Latch_In is the second level. The second control signal Ds_c maintains the previous level when the second enable signal En_latch is disabled.

The test mode controller 2 uses the second control signal Ds_c to control a chip connected thereto to operate in the test mode or the normal mode, wherein chip can be the chip with self-testing. In the other exemplary embodiment, the chip and the test mode controller 2 may be packaged together, and that is, the chip may comprise the test mode controller 2.

Referring to FIG. 2 and FIG. 3, FIG. 3 is a waveform diagram showing waveforms of multiple signals generated by the test mode controller in FIG. 2 according to one exemplary embodiment of the present disclosure. When the circuit of the chip is powered on (i.e. the power signal changes to the second level from the first level), since the functions of the chip are in the warm-up states, the enable signal generator 22 continuously enables the first enable signal En_cmp and the second enable signal En_latch for a start-up time T_START_UP.

During the start-up time T_START_UP, the power indicating voltage CSI is connected to the negative voltage, and thus the control signal generator 21 generates the first control signal Latch_In with the second level. When the start-up time T_START_LTP elapses, the enable signal generator 22 continuously enables the first enable signal En_cmp for the delay time T_DELAY. In other words, the enable signal generator 22 continuously enables the first enable signal En_cmp for THE start-up time T_START_UP and the delay time T_DELAY when the power signal VDD changes to the second level from the first level.

Since the first enable signal En_cmp is enabled for the additional delay time T_DELAY, it guarantees that the latch 23 can obtain the stable first control signal Latch_In when the second enable signal En_Latch is enabled. During the start-up time T_START_UP and the delay time T_DELAY, the control signal generator 21 generates first control signal Latch_In with the second level correspondingly.

During the start-up time T_START_UP, the second enable signal En_Latch is enabled, the first control signal Latch_In is second level, and therefore the latch 23 outputs the second control signal Ds_c with the second level. Then, when the start-up time T_START_UP elapses, and before the test time T_TEST begins, the second enable signal En_Latch maintains disabled, and thus the latch 23 holds the outputted second control signal Ds_c with the second level.

During the start-up time T_START_UP, the counting function of the enable signal generator 22 is disabled. However, when the start-up time T_START_UP elapses, the second enable signal En_Latch is disabled. Meanwhile, the second control signal Ds_c is the second level, and that is, the chip has been warm up, and can begin to operate in the test mode, therefore enabling the counting function of the enable signal generator 22.

When enable signal generator 22 has counted for the test time T_TEST, the enable signal generator 22 briefly enables the second enable signal En_Latch for a pulse time T_PULSE. In other words, the enable signal generator 22 continuously enables the second enable signal En_Latch for the start-up time T_START_UP when the power signal VDD changes to the second level from the first level, and briefly enables the second enable signal En_Latch for a pulse time T_PULSE when the test time T_TEST elapses.

When the delay time T_DELAY elapses, the first enable signal En_cmp is disabled. Thus, the control signal generator 21 outputs the first control signal Latch_In with the first level. When the test time T_TEST elapses, the second enable signal En_Latch is briefly enabled during the pulse time T_PULSE, and meanwhile the first control signal Latch_In is the first level, such that the latch 23 outputs the second control signal Ds_c with the first level. The second control signal Ds_c with the first level controls the chip to operate in the normal mode from test mode.

When the noise factor or the other problems makes the chip operate in the test mode erroneously, the test mode controller 2 can control the chip to operate in the normal when the test time T_TEST elapses. Accordingly, the test mode controller 2 does not need the additional test pin, and can further protect the chip erroneously operate in the test mode for a long time due to the noise factor or the other problems.

It is noted that, in the illustrated exemplary embodiment, although the first level is 0V, and the second level is 3.9V, the voltages of the first level and the second level are not intended to limit the scope of the present disclosure. In the similar manner, in the illustrated exemplary embodiment, although the enabled voltage is 3.9V, and the disabled voltage is 0V, levels of the enabled voltage and the disabled voltage are intended to limit the scope of the present disclosure.

### Another One Exemplary Embodiment of The Test Mode Controller

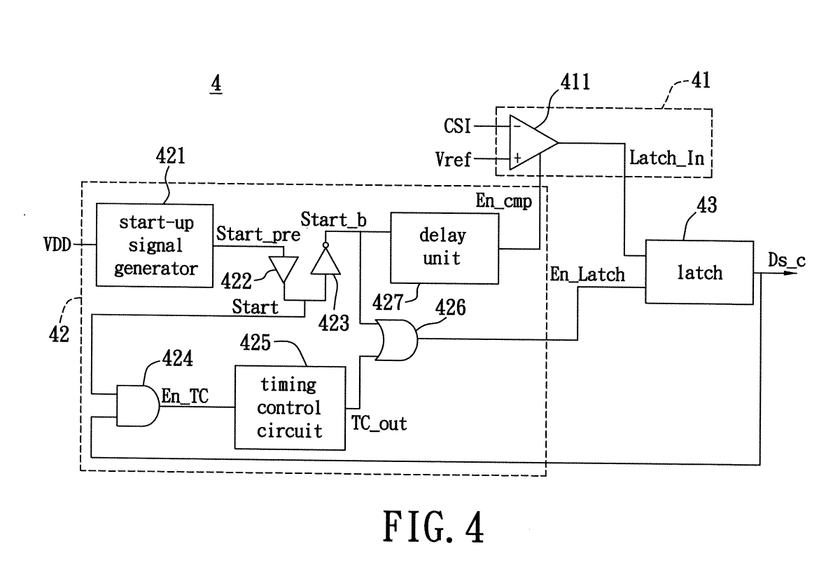

Referring to FIG. 4, FIG. 4 is a circuit diagram showing a test mode controller according to another one exemplary embodiment of the present disclosure. The test mode controller 4 comprises a control signal generator 41, an enable signal generator 42, and a latch 43. The control signal generator 41 comprises a comparator 411, and the enable signal generator 42 comprises a start-up signal generator 421, a buffer 422, an inverter 423, a delay unit 427, an AND gate 424, a timing control circuit 425, and an OR gate 426. The start-up signal generator 421 is electrically coupled to the buffer 422, and the buffer 422 is electrically coupled to the AND gate 424 and the inverter 423. The inverter 423 is electrically coupled to the OR gate 426 and the delay unit 427, and the delay unit 427 is electrically coupled to the comparator 411. The AND gate 424 is electrically coupled to the latch 43 and the timing control circuit 425, and the OR gate 426 is electrically coupled to the timing control circuit 425 and the latch43.

The comparator 411 is controlled by the first enable signal En_cmp, and the negative input end and the positive input end of the comparator 411 respectively receives the power indicating voltage CSI and the reference voltage Vref. When the first enable signal En_cmp is enabled, and the reference voltage Vref is larger than the power indicating voltage CSI, the comparator 411 generates the first control signal Latch_In with the second level. When the first enable signal En_cmp is disabled, the comparator 411 outputs the first control signal Latch_In with the first level.

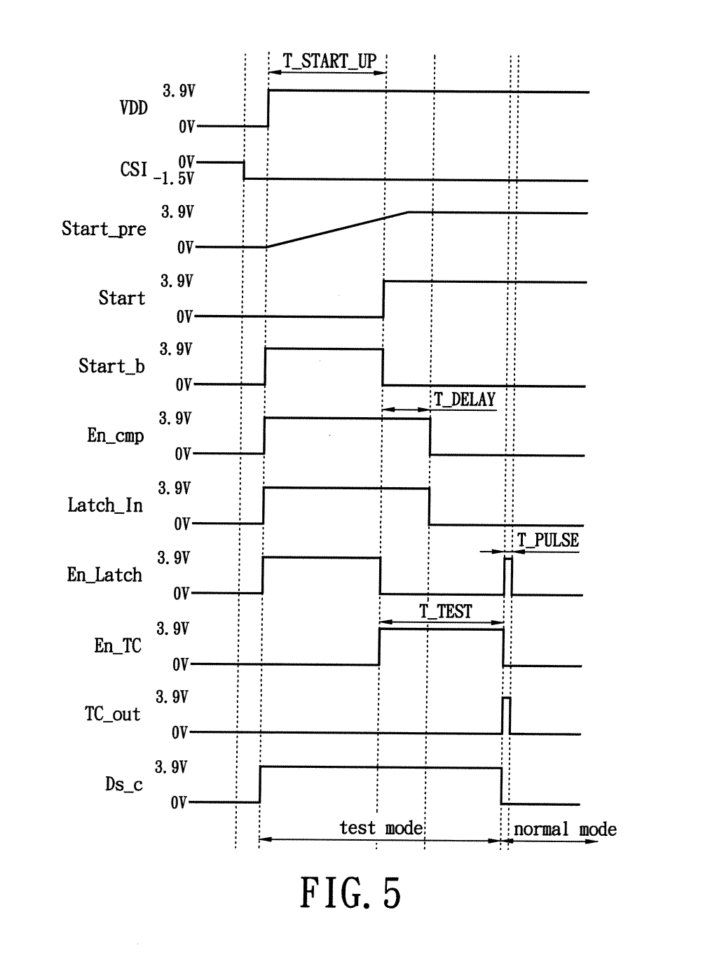

Referring to FIG. 4 and FIG. 5, FIG. 5 is a waveform diagram showing waveforms of multiple signals generated by the test mode controller in FIG. 4 according to one exemplary embodiment of the present disclosure. When the chip is powered on (i.e. the power signal VDD changes to the second level from the first level), the functions of the chip are in the warm-up states. Hence, the start-up signal generator 421 generates the pre-start signal Start_pre when the power signal VDD changes to the second level from the first level, wherein the pre-start signal Start_pre changes to the second level from the first level during the start-up time T_START_UP.

The buffer 422 buffers the pre-start signal Start_pre, and outputs the start signal Start, wherein the start signal Start is the first level during the start-up time T_START_UP, and the start signal Start is the second level when the start-up time T_START_UP elapses. The inverter 423 receives the start signal Start, and outputs the inverted start signal Start_b, wherein the inverted start signal Start_b is an inverted signal of the start signal Start.

The delay unit 427 receives the inverted start signal Start_b. When the inverted start signal Start_b does not changes to the first level from the second level, the delay unit 427 outputs the inverted start signal Start_b as the first control signal Latch_In. By contrast, when the inverted start signal Start_b changes to the first level from the second level, the delay unit 427 delays the inverted start signal Start_b for the delay time T_DELAY, and outputs the delayed inverted first enable signal En_cmp as the first control signal Latch_In. In other words, the first enable signal En_cmp is enabled for the start-up time T_START_UP and the delay time T_DELAY. During the start-up time T_START_UP and the delay time T_DELAY, the comparator 411 correspondingly generates the first control signal Latch_In with the second level.

To put it concretely, during the start-up time T_START_UP and the delay time T_DELAY, the power indicating voltage CSI is connected a negative voltage. Meanwhile, since the first enable signal En_cmp is enabled, the control signal generator 21 generates the first control signal Latch_In with the second level.

The OR gate 426 performs the logic OR operation on the timing count output signal TC_out and the inverted start signal Start_b, so as to generate the second enable signal En_latch. Since the inverted start signal Start_b is the second level during the start-up time T_START_UP, the second enable signal En_latch is continuously enabled during the start-up time T_START_UP. Thus, the latch43 outputs the second control signal Ds_c with the second level during the start-up time T_START_UP.

The AND gate 424 performs the logic AND operation on the start signal Start and the second control signal Ds_c, so as to generates the timing control enable signal En_TC. When the start-up time T_START_UP elapses, the start signal Start is the second level, and the second control signal Ds_c is also the second level, such that the AND gate 424 outputs the timing control enable signal En_TC being enabled.

The timing control circuit 425 counts the test time T_TEST when the timing control enable signal En_TC is enabled. When the test time T_TEST elapses, the timing control circuit 425 outputs the timing count output signal TC_out, wherein the timing count output signal TC_out is briefly enabled for the pulse time T_PULSE when the test time T_TEST elapses. Accordingly, when the start-up time T_START_UP elapses, the timing control circuit 425 is enabled. When the test time T_TEST elapses, the timing count output signal TC_out is briefly enabled for the pulse time T_PULSE.

When the delay time T_DELAY elapses, the first enable signal En_cmp is disabled, and therefore the comparator output the first control signal Latch_In with the first level. When the test time T_TEST elapses, the second enable signal En_Latch is briefly enabled for the pulse time T_PULSE, and the first control signal Latch_In is the first level. Meanwhile, the latch 23 outputs the second control signal Ds_c with the first level. The second control signal Ds_c with the first level makes the chip operate in the normal mode from the test mode.

The test mode controller 4 may achieve the similar results as those of the test mode controller 2 in FIG. 2, such that the test mode controller 4 does not need the additional test pin, and can further protect the chip erroneously operate in the test mode for a long time due to the noise factor or the other problems.

### Another One Exemplary Embodiment of The Test Mode Controller

Referring to FIG. 2 and FIG. 6, FIG. 6 is a waveform diagram showing waveforms of multiple signals generated by the test mode controller in FIG. 2 according to another one exemplary embodiment of the present disclosure. In FIG. 3, to prevent that the operation speed of the enable signal generator 22 is less than the transient speed of the power signal VDD, the start-up time T_START_UP is needed. Generally speaking, the power signal VDD may not change to the second from the first level in a flash. As shown in FIG. 6, the power signal VDD gradually changes to the second level from the first level during the rise time T_RISE.

The waveform diagram of FIG. 6 is similar to that of FIG. 3, and the difference between them is illustrated as follows. The start-up time T_START_UP does not exist in the waveform diagram of FIG. 6, and the rise time T_RISE of the power signal VDD is shown in FIG. 6 instead. The person skilled in the art can replace the start-up time T_START_UP with the rise time T_RISE of the power signal VDD, and refer to the descriptions of FIG. 3 to understand relations of the waveforms of the signals in FIG. 6, therefore omitting the detailed and repeated descriptions. It is noted that, in the exemplary embodiment of FIG. 6, the operation speed of the control signal generator 21 is not less than the transient speed of the power signal VDD.

### Another One Exemplary Embodiment of The Test Mode Controller

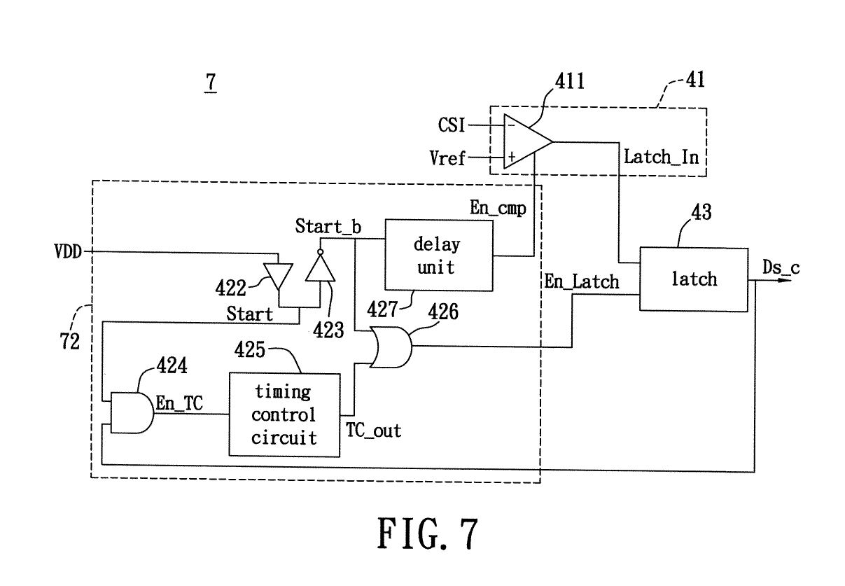

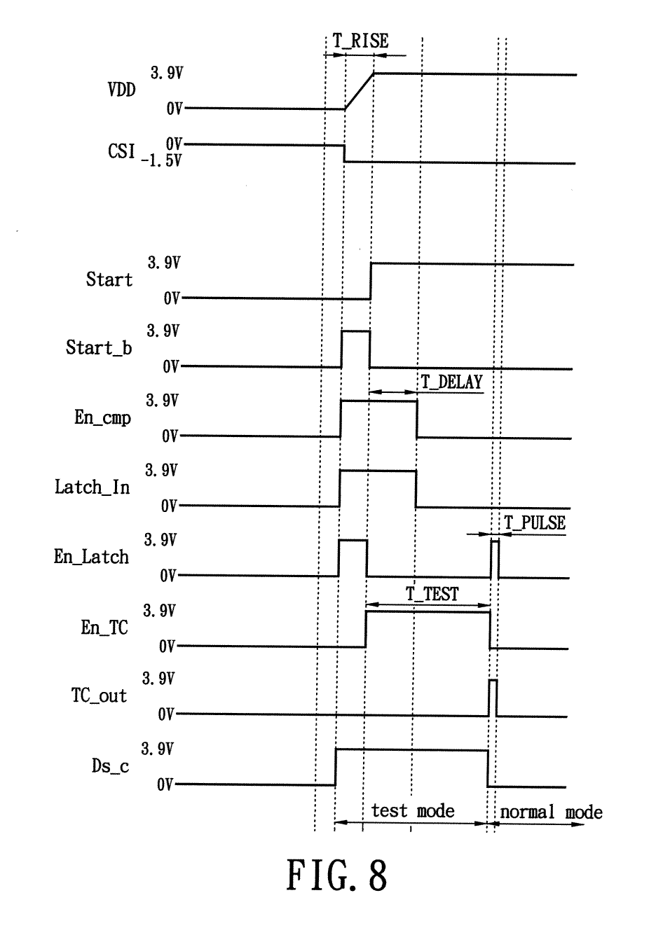

Referring to FIG. 7 and FIG. 8, FIG. 7 is a circuit diagram showing a test mode controller according to another one exemplary embodiment of the present disclosure, and FIG. 8 is a waveform diagram showing waveforms of multiple signals generated by the test mode controller in FIG. 7 according to one exemplary embodiment of the present disclosure. The difference between FIG. 7 and FIG. 4 is illustrated as follows. The enable signal generator 72 does not have the start-up signal generator 421 shown in FIG. 4. The difference between FIG. 8 and FIG. 5 is also illustrated as follows. The start-up time T_START_UP and the pre-start signal Start_pre shown in FIG. 5 do not exist in FIG. 8.

In the exemplary embodiments of FIG. 5 and FIG. 6, to prevent that the operation speed of the comparator 411 is less than the transient speed of the power signal VDD, the additional start-up time T_START_UP and the pre-start signal Start_pre are required. When the operation speed of the comparator 411 is not less than the transient speed of the power signal VDD, the test mode controller can be implemented by the exemplary embodiments of FIG. 7 and FIG. 8.

In FIG. 7 and FIG. 8, the person skilled in the art can replace the start-up time T_START_UP of the power signal VDD and the pre-start signal Start-pre respectively with the rise time T_RISE of the power signal VDD and the power signal VDD, and refer to the descriptions of FIG. 5 to understand relations of the waveforms of the signals in FIG. 8, therefore omitting the detailed and repeated descriptions.

### An Exemplary Embodiment of The Electronic Apparatus with Self-Testing

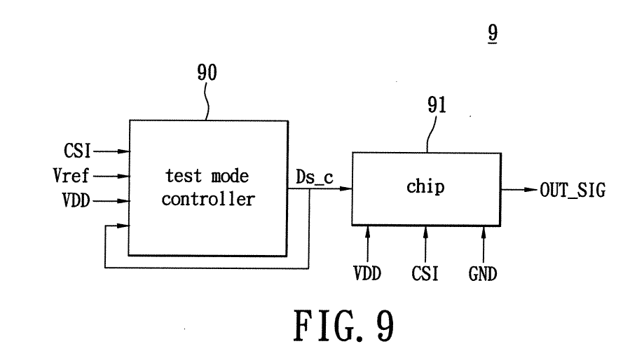

Referring to FIG. 9, FIG. 9 is a circuit diagram showing an electronic apparatus with self-testing according to one exemplary embodiment of the present disclosure. The electronic apparatus with self-testing 9 comprises a chip 91 and a test mode controller 90. The chip 91 receives second the control signal Ds_c generated from the test mode controller 90, and generates the output signal OUT_SIG correspondingly. The chip 91 is electrically coupled to the power signal VDD, the power indicating voltage CSI, and the ground pin GND. Though the chip 91 in FIG. 9 merely outputs one output signal OUT_SIG, the chip 91 is not limited thereto, and that is, the chip 91 may output more than one output signals.

The test mode controller 90 is electrically coupled to the power signal VDD, the power indicating voltage CSI, and the reference voltage Vref. The test mode controller 90 outputs the second control signal Ds_c, wherein the second control signal Ds_c is used to control the chip 91 to operate in the test mode or the normal mode. In addition, the test mode controller 90 may be one of the above test mode controllers 2, 4, 7, and the modification or alteration of the above test mode controllers 2, 4, 7.

### Possible Result of Exemplary Embodiments

In summary, the test mode controller provided by one the exemplary embodiments of the present disclosure may generate a second control signal to control a chip in the electronic apparatus with self-testing to operate in a test mode or a normal mode. Furthermore, the test mode controller and the electronic apparatus with self-testing may not need the test pin required by the conventional chip, but still may reduce the test time as the conventional chip with the test pin. Therefore, the chip area and the package cost of the electronic apparatus with self-testing provided by the exemplary chip of the present disclosure may be lower than those of the conventional chip with the test pin.

The above-mentioned descriptions represent merely the exemplary embodiment of the present disclosure, without any intention to limit the scope of the present disclosure thereto. Various equivalent changes, alternations or modifications based on the claims of present disclosure are all consequently viewed as being embraced by the scope of the present disclosure.

What is claimed is:

1. A test mode controller, comprising:
an enable signal generator, receiving a power signal and a second control signal, and generating a first enable signal and a second enable signal;
a control signal generator, receiving a power indicating voltage and a reference voltage, and generating a first control signal according to the power indicating voltage and the reference voltage when the first enable signal is enabled; and
a latch, controlled by the second enable signal, and outputting the second control signal according to the first control signal when the second enable signal is enabled, wherein the second control signal is used to control a chip to operate in a test mode or a normal mode.

2. The test mode controller according to claim 1, wherein when the power signal changes to a second level from a first level, the enable signal generator continuously enables the second enable signal for a start-up time, and after a test time when the start-up time elapses, the enable signal generator briefly enables the second enable signal for a pulse time; when the power signal changes to the second level from the first level, the enable signal generator continuously enables the first enable signal for the start-up time and a delay time.

3. The test mode controller according to claim 1, wherein when the first enable signal is disabled, the control signal generator outputs the first control signal with the first level.

4. The test mode controller according to claim 3, wherein the control signal generator comprises a comparator, the comparator is controlled by the first enable signal, a negative input end and a positive input end of the comparator respectively receive the power indicating voltage and the reference voltage, wherein when the first enable signal is enabled, and the reference voltage is larger than the power indicating voltage, the comparator generates the first control signal with the second level; when the first enable signal is disabled, the comparator generates the first control signal with the first level.

5. The test mode controller according to claim 2, wherein when the power signal changes to the second level from the first level, the enable signal generator generates pre-start signal, wherein the pre-start signal gradually changes to the second level from the first level during the start-up time; the enable signal generator generates a start signal and an inverted start signal according to the pre-start signal, wherein the inverted start signal is an inverted signal of the start signal, the start signal is the first level during the start-up time, and the start signal is the second level when the start-up time elapses; when the inverted start signal does not changed to the first level from the second level, the enable signal generator outputs the inverted start signal as the first enable signal, when the inverted start signal changes to the first level from the second level, the enable signal generator delays the inverted start signal for the delay time, and outputs the delayed inverted start signal as the first enable signal; the enable signal generator performs a logic AND operation on the start signal and the second control signal, so as to generates a timing control enable signal; when the timing control enable signal is enabled, the enable signal generator counts the test time, and when the test time elapses, the enable signal generator generates a timing count output signal, wherein the timing count output signal is briefly enabled for the pulse time when the test time elapses;
the enable signal generator performs a logic OR operation on the timing count output signal and the inverted start signal, so as to generate the second enable signal.

6. The test mode controller according to claim 2, wherein the enable signal generator comprises:
a start-up signal generator, generating a pre-start signal when the power signal changes from a second level to a first level, wherein the pre-start signal gradually changes to the second level from the first level during a start-up time;
a buffer, buffering the pre-start signal, and generating a start signal correspondingly, wherein the start signal is the first level during the start-up time, and the start signal is the second level when the start-up time elapses;
an inverter, receiving the start signal, and outputting an inverted start signal, wherein the inverted start signal is an inverted signal of the start signal;
a delay unit, receiving the inverted start signal, outputting the inverted start signal as the first enable signal when the inverted start signal does not change to the first level from the second level, delaying inverted start signal and outputting the delayed inverted start signal as the first enable signal when the inverted start signal changes to the first level from the second level;
an AND gate, performing a logic AND operation on the start signal and the second control signal, so as to generates a timing control enable signal;
a timing control circuit, counting the test time when the timing control enable signal is enabled, and outputting a timing count output signal when the test time elapses, wherein the timing count output signal is briefly enabled for the pulse time when the test time elapses; and
an OR gate, performing a logic OR operation on the timing count output signal and the inverted start signal, so as to generates the second enable signal.

7. The test mode controller according to claim 1, wherein when the power signal gradually changes to a second level from a first level during a rise time, the enable signal generator continuously enables the second enable signal for the rise time, and after a test time when the rise time elapses, the enable signal generator briefly enables the second enable signal for a pulse time;
when the power signal changes to the second level from the first level during the rise time, the enable signal generator continuously enables the first enable signal for the rise time and a delay time

8. The test mode controller according to claim 7, wherein the enable signal generator generates a start signal and an inverted start signal according to the power signal, wherein the inverted start signal is an inverted signal of the start signal, the start signal is the first level during the rise time, and the start signal is the second level when the rise time elapses; when the inverted start signal does not changed to the first level from the second level, the enable signal generator outputs the inverted start signal as the first enable signal, when the inverted start signal changes to the first level from the second level, the enable signal generator delays the inverted start signal for the delay time, and outputs the delayed inverted start signal as the first enable signal; the enable signal generator performs a logic AND operation on the start signal and the second control signal, so as to generates a timing control enable signal; when the timing control enable signal is enabled, the enable signal generator counts the test time, and when the test time elapses, the enable signal generator generates a timing count output signal, wherein the timing count output signal is briefly enabled for the pulse time when the test time elapses; the enable signal generator performs a logic OR operation on the timing count output signal and the inverted start signal, so as to generate the second enable signal.

9. The test mode controller according to claim 7, wherein the enable signal generator comprises:
a buffer, buffering the power signal, and generating a start signal correspondingly, wherein the start signal is the first level during the rise time, and the start signal is the second level when the rise time elapses;
an inverter, receiving the start signal, and outputting an inverted start signal, wherein the inverted start signal is an inverted signal of the start signal;
a delay unit, receiving the inverted start signal, outputting the inverted start signal as the first enable signal when the inverted start signal does not change to the first level from the second level, delaying inverted start signal and outputting the delayed inverted start signal as the first enable signal when the inverted start signal changes to the first level from the second level;
an AND gate, performing a logic AND operation on the start signal and the second control signal, so as to generates a timing control enable signal;
a timing control circuit, counting the test time when the timing control enable signal is enabled, and outputting a timing count output signal when the test time elapses, wherein the timing count output signal is briefly enabled for the pulse time when the test time elapses; and
an OR gate, performing a logic OR operation on the timing count output signal and the inverted start signal, so as to generates the second enable signal.

10. An electronic apparatus with self-testing, comprising:
a chip, receiving a second control signal to determine whether the chip operate in a test mode or a normal mode;
a test mode controller, comprising:
an enable signal generator, receiving a power signal and the second control signal, and generating a first enable signal and a second enable signal;
a control signal generator, receiving a power indicating voltage and a reference voltage, and generating a first control signal according to the power indicating voltage and the reference voltage when the first enable signal is enabled; and
a latch, controlled by the second enable signal, and outputting the second control signal according to the first control signal when the second enable signal is enabled.

11. The electronic apparatus according to claim 10, wherein when the power signal changes to a second level from a first level, the enable signal generator continuously enables the second enable signal for a start-up time, and after a test time when the start-up time elapses, the enable signal generator briefly enables the second enable signal for a pulse time; when the power signal changes to the second level from the first level, the enable signal generator continuously enables the first enable signal for the start-up time and a delay time.

12. The electronic apparatus r according to claim 10, wherein when the first enable signal is disabled, the control signal generator outputs the first control signal with the first level.

13. The electronic apparatus according to claim 12, wherein the control signal generator comprises a comparator, the comparator is controlled by the first enable signal, a negative input end and a positive input end of the comparator respectively receive the power indicating voltage and the reference voltage, wherein when the first enable signal is enabled, and the reference voltage is larger than the power indicating voltage, the comparator generates the first control signal with the second level; when the first enable signal is disabled, the comparator generates the first control signal with the first level.

14. The electronic apparatus according to claim 11, wherein when the power signal changes to the second level from the first level, the enable signal generator generates pre-start signal, wherein the pre-start signal gradually changes to the second level from the first level during the start-up time; the enable signal generator generates a start signal and an inverted start signal according to the pre-start signal, wherein the inverted start signal is an inverted signal of the start signal, the start signal is the first level during the start-up time, and the start signal is the second level when the start-up time elapses; when the inverted start signal does not changed to the first level from the second level, the enable signal generator outputs the inverted start signal as the first enable signal, when the inverted start signal changes to the first level from the second level, the enable signal generator delays the inverted start signal for the delay time, and outputs the delayed inverted start signal as the first enable signal; the enable signal generator performs a logic AND operation on the start signal and the second control signal, so as to generates a timing control enable signal; when the timing control enable signal is enabled, the enable signal generator counts the test time, and when the test time elapses, the enable signal generator generates a timing count output signal, wherein the timing count output signal is briefly enabled for the pulse time when the test time elapses; the enable signal generator performs a logic OR operation on the timing count output signal and the inverted start signal, so as to generate the second enable signal.

15. The electronic apparatus according to claim 11, wherein the enable signal generator comprises:
a start-up signal generator, generating a pre-start signal when the power signal changes from a second level to a first level, wherein the pre-start signal gradually changes to the second level from the first level during a start-up time;
a buffer, buffering the pre-start signal, and generating a start signal correspondingly, wherein the start signal is the first level during the start-up time, and the start signal is the second level when the start-up time elapses;
an inverter, receiving the start signal, and outputting an inverted start signal, wherein the inverted start signal is an inverted signal of the start signal;
a delay unit, receiving the inverted start signal, outputting the inverted start signal as the first enable signal when the inverted start signal does not change to the first level from the second level, delaying inverted start signal and outputting the delayed inverted start signal as the first enable signal when the inverted start signal changes to the first level from the second level;
an AND gate, performing a logic AND operation on the start signal and the second control signal, so as to generates a timing control enable signal;
a timing control circuit, counting the test time when the timing control enable signal is enabled, and outputting a timing count output signal when the test time elapses, wherein the timing count output signal is briefly enabled for the pulse time when the test time elapses; and
an OR gate, performing a logic OR operation on the timing count output signal and the inverted start signal, so as to generates the second enable signal.

16. The electronic apparatus according to claim 10, wherein when the power signal gradually changes to a second level from a first level during a rise time, the enable signal generator continuously enables the second enable signal for the rise time, and after a test time when the rise time elapses, the enable signal generator briefly enables the second enable signal for a pulse time;
when the power signal changes to the second level from the first level during the rise time, the enable signal generator continuously enables the first enable signal for the rise time and a delay time

17. The electronic apparatus according to claim 16, wherein the enable signal generator generates a start signal and an inverted start signal according to the power signal, wherein the inverted start signal is an inverted signal of the start signal, the start signal is the first level during the rise time, and the start signal is the second level when the rise time elapses; when the inverted start signal does not changed to the first level from the second level, the enable signal generator outputs the inverted start signal as the first enable signal, when the inverted start signal changes to the first level from the second level, the enable signal generator delays the inverted start signal for the delay time, and outputs the delayed inverted start signal as the first enable signal; the enable signal generator performs a logic AND operation on the start signal and the second control signal, so as to generates a timing control enable signal; when the timing control enable signal is enabled, the enable signal generator counts the test time, and when the test time elapses, the enable signal generator generates a timing count output signal, wherein the timing count output signal is briefly enabled for the pulse time when the test time elapses; the enable signal generator performs a logic OR operation on the timing count output signal and the inverted start signal, so as to generate the second enable signal.

18. The electronic apparatus according to claim 16, wherein the enable signal generator comprises:
a buffer, buffering the power signal, and generating a start signal correspondingly, wherein the start signal is the first level during the rise time, and the start signal is the second level when the rise time elapses;
an inverter, receiving the start signal, and outputting an inverted start signal, wherein the inverted start signal is an inverted signal of the start signal;
a delay unit, receiving the inverted start signal, outputting the inverted start signal as the first enable signal when the inverted start signal does not change to the first level from the second level, delaying inverted start signal and outputting the delayed inverted start signal as the first enable signal when the inverted start signal changes to the first level from the second level;
an AND gate, performing a logic AND operation on the start signal and the second control signal, so as to generates a timing control enable signal;
a timing control circuit, counting the test time when the timing control enable signal is enabled, and outputting a timing count output signal when the test time elapses, wherein the timing count output signal is briefly enabled for the pulse time when the test time elapses; and
an OR gate, performing a logic OR operation on the timing count output signal and the inverted start signal, so as to generates the second enable signal.
